(19) United States
(12) Patent Application Publication
(10) Pub. No.: US 2026/0068340 A1
(43) Pub. Date: Mar. 5, 2026

(54) SENSOR PACKAGE STRUCTURE

(71) Applicant: TONG HSING ELECTRONIC INDUSTRIES, LTD., Taoyuan City (TW)

(72) Inventors: CHIEN-CHEN LEE, Taoyuan City (TW); LI-CHUN HUNG, Taoyuan City (TW); JUI-HUNG HSU, Taoyuan City (TW)

(21) Appl. No.: 19/383,780

(22) Filed: Nov. 10, 2025

Related U.S. Application Data
(63) Continuation of application No. 17/741,421, filed on May 10, 2022.

(30) Foreign Application Priority Data
Dec. 21, 2021 (TW) 110147817

(51) Int. Cl. H10F 39/00

(52) U.S. Cl. CPC H10F 39/804; H10F 39/8057; H10F 39/811

(57) ABSTRACT

A sensor package structure includes a substrate, a sensor chip disposed on and electrically coupled to the substrate, an infrared light curing layer being in a ringed shape and disposed on the sensor chip, a light-permeable layer arranged above the sensor chip through the infrared light curing layer, and a visible light shielding layer that is in a ringed shape and that is disposed on the light-permeable layer. A sensing region of the sensor chip faces the light-permeable layer. The visible light shielding layer can block a visible light from passing therethrough, and has an opening located directly above the sensing region. The infrared light curing layer is located in a projection space defined by orthogonally projecting the visible light shielding layer toward the substrate, and the visible light shielding layer only allows an infrared light to travel onto the infrared light curing layer by passing therethrough.

### CROSS-REFERENCE TO RELATED PATENT APPLICATION

This application is a continuation of the U.S. patent application Ser. NO. 17/741,421 filed on May 10, 2022 and entitled “SENSOR PACKAGE STRUCTURE”. The entirety of the above-mentioned patent application is hereby incorporated by reference herein and made as a part of this specification.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure.

### BACKGROUND OF THE DISCLOSURE

A conventional sensor package structure is formed by disposing a glass board onto a sensor chip through an adhesive, and the adhesive is arranged around a sensing region of the sensor chip. However, since light passing through the glass board may be partially reflected by the adhesive, the reflected light may affect the sensing region of the sensor chip (e.g., from a flare phenomenon). Moreover, the adhesive of the conventional sensor package structure is solidified by heating, so that a levelness of the glass board is difficult to be controlled.

### SUMMARY OF THE DISCLOSURE

In response to the above-referenced technical inadequacies, the present disclosure provides a sensor package structure to effectively improve on the issues associated with conventional sensor package structures.

In one aspect, the present disclosure provides a sensor package structure, which includes a substrate, a sensor chip, an infrared light curing layer, a light-permeable layer, and a visible light shielding layer. The sensor chip is disposed on and electrically coupled to the substrate. Moreover, a top surface of the sensor chip includes a sensing region and a carrying region that surrounds the sensing region. The infrared light curing layer is in a ringed shape and is disposed on the carrying region of the sensor chip. The light-permeable layer is arranged above the sensor chip through the infrared light curing layer. The light-permeable layer, the infrared light curing layer, and the sensor chip jointly define an enclosed space, and the sensing region faces the light-permeable layer. The visible light shielding layer is in a ringed shape and is disposed on the light-permeable layer. The visible light shielding layer is configured to block a visible light from passing therethrough, and the visible light shielding layer has an opening that is defined by an inner edge thereof and that is located directly above the sensing region. The infrared light curing layer is located in a projection space defined by orthogonally projecting the visible light shielding layer toward the substrate, and the visible light shielding layer only allows an infrared light to travel onto the infrared light curing layer by passing therethrough.

Therefore, through structural cooperation between the infrared light curing layer and the visible light shielding layer, the sensor package structure of the present disclosure can provide a number of technical effects; for example, under a premise that the visible light shielding layer can block the visible light to reduce an effect of the glare phenomenon caused by the reflection from the infrared light curing layer, the visible light shielding layer only allows the infrared light to pass therethrough for solidifying the infrared light curing layer, so that the solidified shape of the infrared light curing layer can meet a predetermined condition, thereby enabling precise control of the levelness of the light-permeable layer.

Moreover, the sensor package structure provided by the present disclosure can be detected by the infrared light according to an optical property of the visible light shielding layer that only allows the infrared light to pass therethrough.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a perspective view of a sensor package structure according to a first embodiment of the present disclosure;

FIG. 2 is a top view of FIG. 1;

FIG. 3 is a cross-sectional view taken along line III-III of FIG. 2;

FIG. 4 is a cross-sectional view of the sensor package structure in another configuration according to the first embodiment of the present disclosure;

FIG. 5 is a perspective view of the sensor package structure according to a second embodiment of the present disclosure;

FIG. 6 is a top view of FIG. 5;

FIG. 7 is a cross-sectional view taken along line VII-VII of FIG. 6 and

FIG. 8 is a cross-sectional view of the sensor package structure in another configuration according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### [First Embodiment]

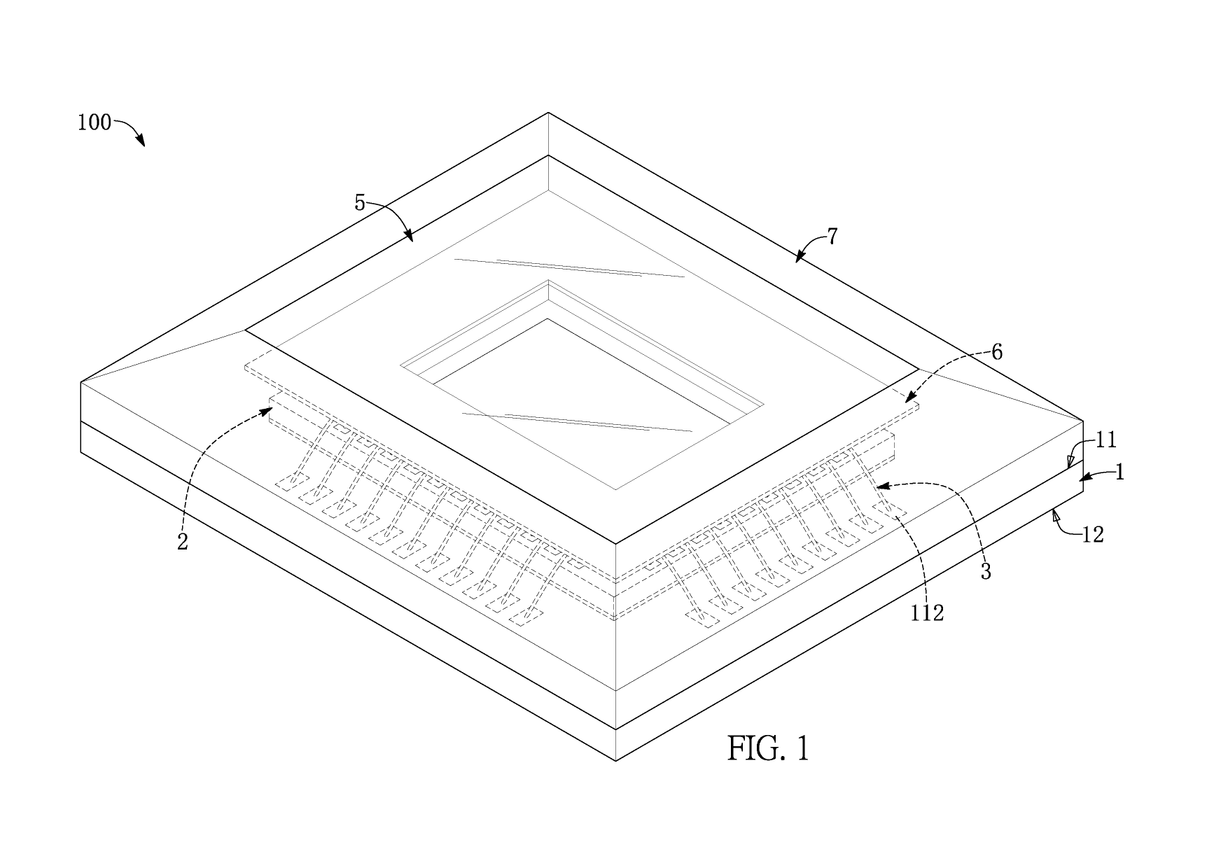

Referring to FIG. 1 to FIG. 4, a first embodiment of the present disclosure provides a sensor package structure 100. In other words, any package structure not encapsulating a sensor chip therein has a structural design different from that of the sensor package structure 100 of the present embodiment.

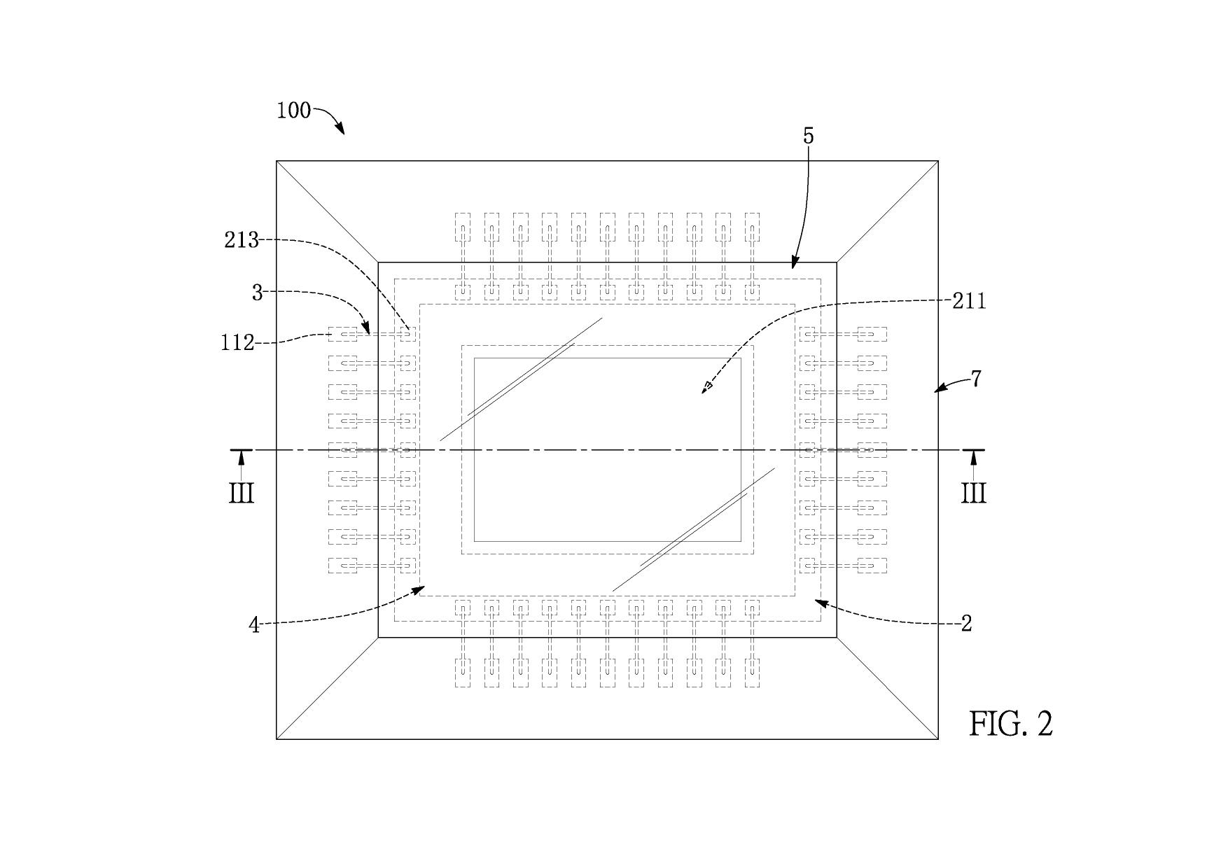

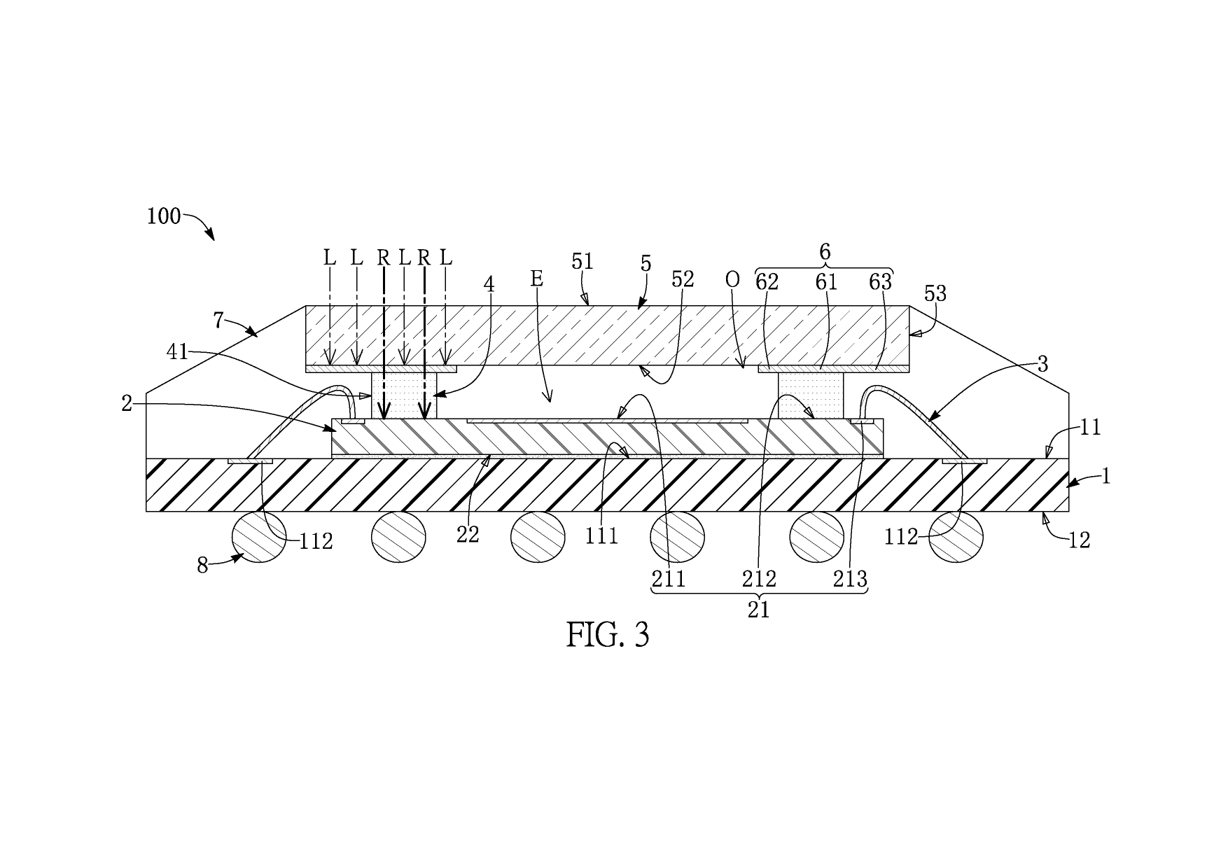

As shown in FIG. 2 and FIG. 3, the sensor package structure 100 includes a substrate 1, a sensor chip 2 disposed on the substrate 1, a plurality of metal wires 3 electrically coupling the sensor chip 2 and the substrate 1, an infrared light curing layer 4 disposed on the sensor chip 2, a light-permeable layer 5 arranged above the sensor chip 2 through the infrared light curing layer 4, a visible light shielding layer 6 disposed on the light-permeable layer 5, and an encapsulating body 7 that is formed on the substrate 1.

The sensor package structure 100 in the present embodiment includes the above components, but can be adjusted or changed according to design requirements. For example, in other embodiments of the present disclosure not shown in the drawings, the sensor package structure 100 can be provided without the metal wires 3, and the sensor chip 2 is fixed onto and electrically coupled to the substrate 1 in a flip-chip manner; or, the encapsulating body 7 of the sensor package structure 100 can be omitted or can be replaced by other structural designs. The structure and connection relationship of each component of the sensor package structure 100 will be described in the following description.

The substrate 1 of the present embodiment is a square-shaped printed circuit board (PCB) or a rectangular PCB, but the present disclosure is not limited thereto. An upper board surface 11 of the substrate 1 includes a chip-bonding region 111 arranged approximately on a center portion thereof, and the substrate 1 includes a plurality of soldering pads 112 that are disposed on the upper board surface 11 and that are arranged outside of the chip-bonding region 111 (or the sensor chip 2). The soldering pads 112 in the present embodiment are in an annular arrangement, but the present disclosure is not limited thereto. For example, in other embodiments of the present disclosure not shown in the drawings, the soldering pads 112 can be arranged in two rows respectively at two opposite sides of the chip-bonding region 111.

In addition, the sensor package structure 100 can further include a plurality of soldering balls 8 disposed on a lower board surface 12 of the substrate 1. The sensor package structure 100 can be soldered onto an electronic component (not shown in the drawings) through the soldering balls 8, thereby electrically connecting the sensor package structure 100 to the electronic component.

The sensor chip 2 in the present embodiment is an image sensing chip, but the present disclosure is not limited thereto. A bottom surface 22 of the sensor chip 2 is fixed onto the chip-bonding region 111 of the substrate 1. In other words, the sensor chip 2 is arranged to be surrounded inside the soldering pads 112. Moreover, a top surface 21 of the sensor chip 2 has a sensing region 211 and a carrying region 212 that has an annular shape surrounding the sensing region 211, and the sensor chip 2 has a plurality of connection pads 213 arranged on the carrying region 212.

Specifically, the quantity and positions of the connection pads 213 of the sensor chip 2 in the present embodiment correspond to those of the soldering pads 112 of the substrate 1. Moreover, one end of each of the metal wires 3 is connected to one of the soldering pads 112, and another end of each of the metal wires 3 is connected to one of the connection pads 213, so that the substrate 1 and the sensor chip 2 can be electrically coupled to each other through the metal wires 3.

The infrared light curing layer 4 is in a ringed shape and is disposed on the carrying region 212 of the sensor chip 2. It should be noted that the infrared light curing layer 4 of the present embodiment is a structure that can be cured by being irradiated with an infrared light R. Accordingly, any adhesive not cured by being irradiated with infrared light is different from the infrared light curing layer 4 of the present embodiment.

The infrared light curing layer 4 in the present embodiment is arranged around (or surrounds) the sensing region 211, and is arranged to be surrounded inside the connection pads 213 (e.g., at least one of the connection pads 213 and the corresponding metal wire 3 connected thereto are located outside of the infrared light curing layer 4), so that a height of the infrared light curing layer 4 is not limited by a height of any one of the metal wires 3, but the present disclosure is not limited thereto.

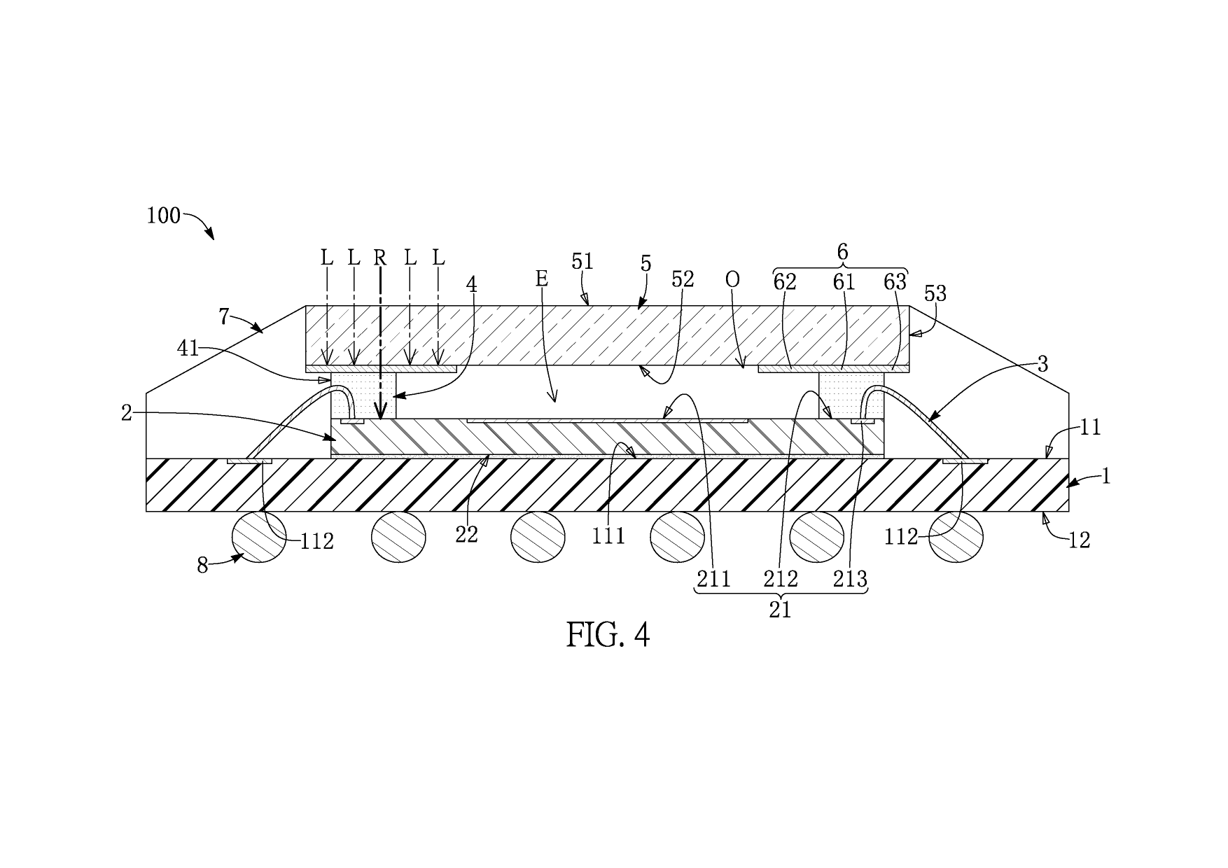

For example, as shown in FIG. 4, the infrared light curing layer 4 can be disposed on the connection pads 213, and covers the connection pads 213 and a part of each of the metal wires 3 (e.g., at least one of the connection pads 213 and a part of the corresponding metal wire 3 connected thereto are embedded in the infrared light curing layer 4).

As shown in FIGS. 2 and 3, the light-permeable layer 5 in the present embodiment is a transparent and flat glass board, but the present disclosure is not limited thereto. The light-permeable layer 5 is arranged above the sensor chip 2 through the infrared light curing layer 4; in other words, the infrared light curing layer 4 is sandwiched between the light-permeable layer 5 and the sensor chip 2. The light-permeable layer 5, the infrared light curing layer 4, and the sensor chip 2 jointly and surroundingly define an enclosed space E, and the sensing region 211 is arranged in the enclosed space E and faces toward the light-permeable layer 5.

Moreover, the light-permeable layer 5 in the present embodiment includes an upper surface 51, a lower surface 52 opposite to the upper surface 51, and a surrounding lateral surface 53 that is connected to the upper surface 51 and the lower surface 52. The lower surface 52 faces toward the sensing region 211, and the outer lateral side 41 of the infrared light curing layer 4 is arranged inward by a distance from the surrounding lateral surface 53 of the light-permeable layer 5, but the present disclosure is not limited thereto. For example, in other embodiments of the present disclosure not shown in the drawings, the surrounding lateral surface 53 of the light-permeable layer 5 can be flush with the outer lateral side 41 of the infrared light curing layer 4.

The visible light shielding layer 6 is in a ringed shape and is disposed on the light-permeable layer 5. The visible light shielding layer 6 is configured to block a visible light L from passing therethrough, and the visible light shielding layer 6 in the present embodiment only allows the infrared light R having a wavelength of at least 780 nm to pass therethrough and is configured to block the visible light L having a wavelength within a range from 365 nm to 780 nm.

Specifically, the visible light shielding layer 6 in the present embodiment is disposed on the lower surface 52 of the light-permeable layer 5. The visible light shielding layer 6 has an opening O that is defined by an inner edge thereof and that is located directly above the sensing region 211, and an outer edge of the visible light shielding layer 6 is flush with the surrounding lateral surface 53 of the light-permeable layer 5.

In other words, the infrared light curing layer 4 is located in a projection space defined by orthogonally projecting the visible light shielding layer 6 toward the substrate 1, and the visible light shielding layer 6 only allows the infrared light R to pass therethrough and travel onto the infrared light curing layer 4. That is to say, any shielding layer that allows light other than infrared light to pass therethrough is different from the visible light shielding layer 6 of the present embodiment.

Accordingly, the arrangement of the visible light shielding layer 6 can be used to effectively reduce the flare phenomenon caused by light reflected from the infrared light curing layer 4, and can be used to allow the infrared light curing layer 4 under the visible light shielding layer 6 to be irradiated by enough curing light (e.g., the infrared light R) such that the infrared light curing layer 4 is entirely solidified. In other words, the sensor package structure 100 of the present embodiment is provided by forming the visible light shielding layer 6 at a specific position so as to reduce the flare phenomenon and to effectively solidify the infrared light curing layer 4.

Specifically, the visible light shielding layer 6 in the present embodiment has a normally shielding segment 61 being in a ringed shape, an inner laterally shielding segment 62 that is in a ringed shape and that inwardly extends from the normally shielding segment 61, and an outer laterally shielding segment 63 that is in a ringed shape and that outwardly extends from the normally shielding segment 61, but the present disclosure is not limited thereto. The normally shielding segment 61 is sandwiched between the light-permeable layer 5 and the infrared light curing layer 4. The inner laterally shielding segment 62 is located in the enclosed space E, and the opening O is defined by an inner edge of the inner laterally shielding segment 62. The outer laterally shielding segment 63 is arranged outside of the infrared light curing layer 4, and an outer edge of the outer laterally shielding segment 63 is flush with the surrounding lateral surface 53 of the light-permeable layer 5.

The encapsulating body 7 is formed on the upper board surface 11 of the substrate 1, and a lateral side of the encapsulating body 7 is flush with that of the substrate 1. The sensor chip 2, the infrared light curing layer 4, the light-permeable layer 5, and at least part of each of the metal wires 3 are embedded in the encapsulating body 7, and a part of the light-permeable layer 5 corresponding in position to the opening O is exposed from the encapsulating body 7. Moreover, the encapsulating body 7 is connected to a part of the visible light shielding layer 6. In other words, the outer laterally shielding segment 63 of the visible light shielding layer 6 is embedded in (and connected to) the encapsulating body 7.

Furthermore, the encapsulating body 7 in the present embodiment is a solidified liquid compound, but the present disclosure is not limited thereto. For example, in other embodiments of the present disclosure not shown in the drawings, the encapsulating body 7 can further include a molding compound formed on a top surface of the solidified liquid compound; or the encapsulating body 7 can be a molding compound.

In summary, through structural cooperation between the infrared light curing layer 4 and the visible light shielding layer 6, the sensor package structure 100 of the present embodiment can provide a number of technical effects as described in the next paragraph. In other words, any package structure not having the technical effects is different from the sensor package structure 100 provided by the present embodiment.

Specifically, under a premise that the visible light shielding layer 6 can block the visible light L to reduce an effect of the glare phenomenon caused by the reflection from the infrared light curing layer 4, the visible light shielding layer 6 only allows the infrared light R to pass therethrough for solidifying the infrared light curing layer 4, so that the solidified shape of the infrared light curing layer 4 can meet a predetermined condition, thereby enabling precise control of the levelness of the light-permeable layer 5. Moreover, the sensor package structure 100 can be detected by the infrared light R (e.g., the solidified shape of the infrared light curing layer 4 can be detected by the infrared light R) according to an optical property of the visible light shielding layer 6 that only allows the infrared light R to pass therethrough.

### [Second Embodiment]

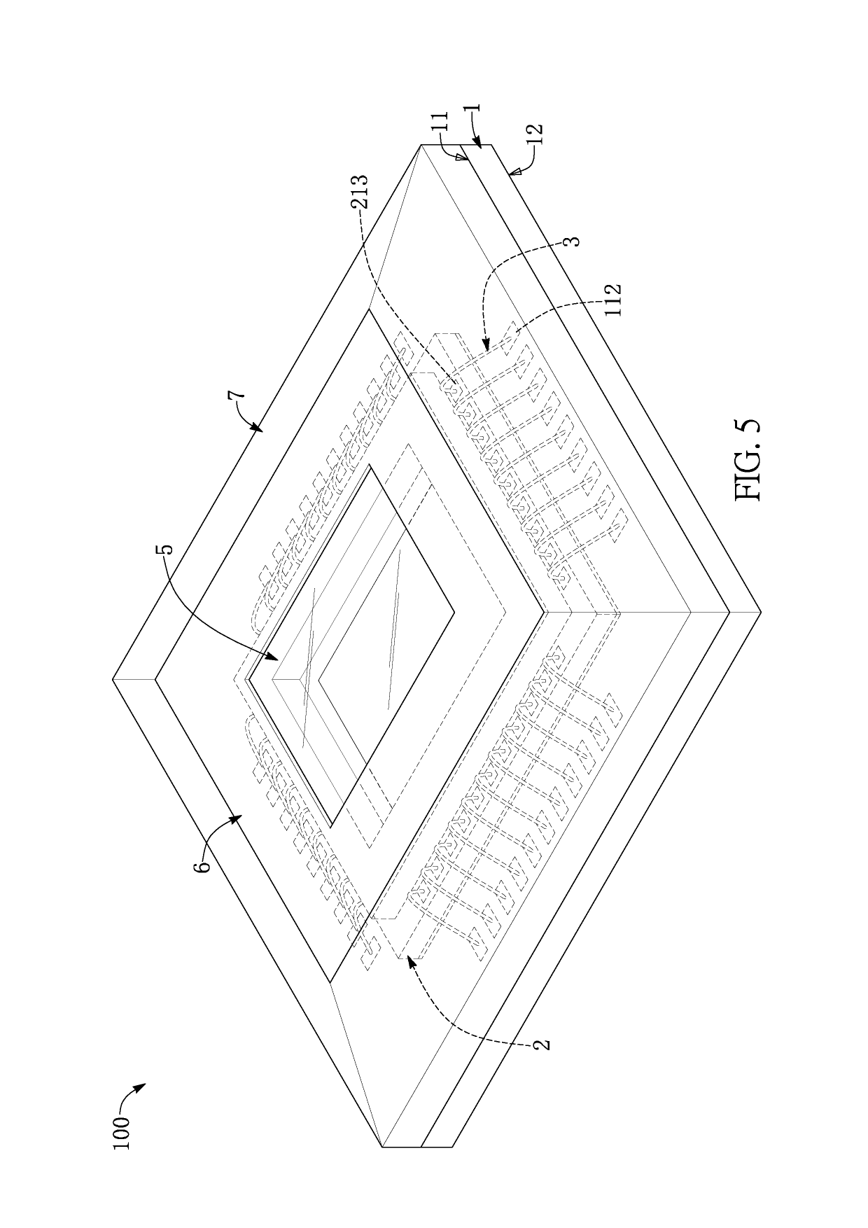

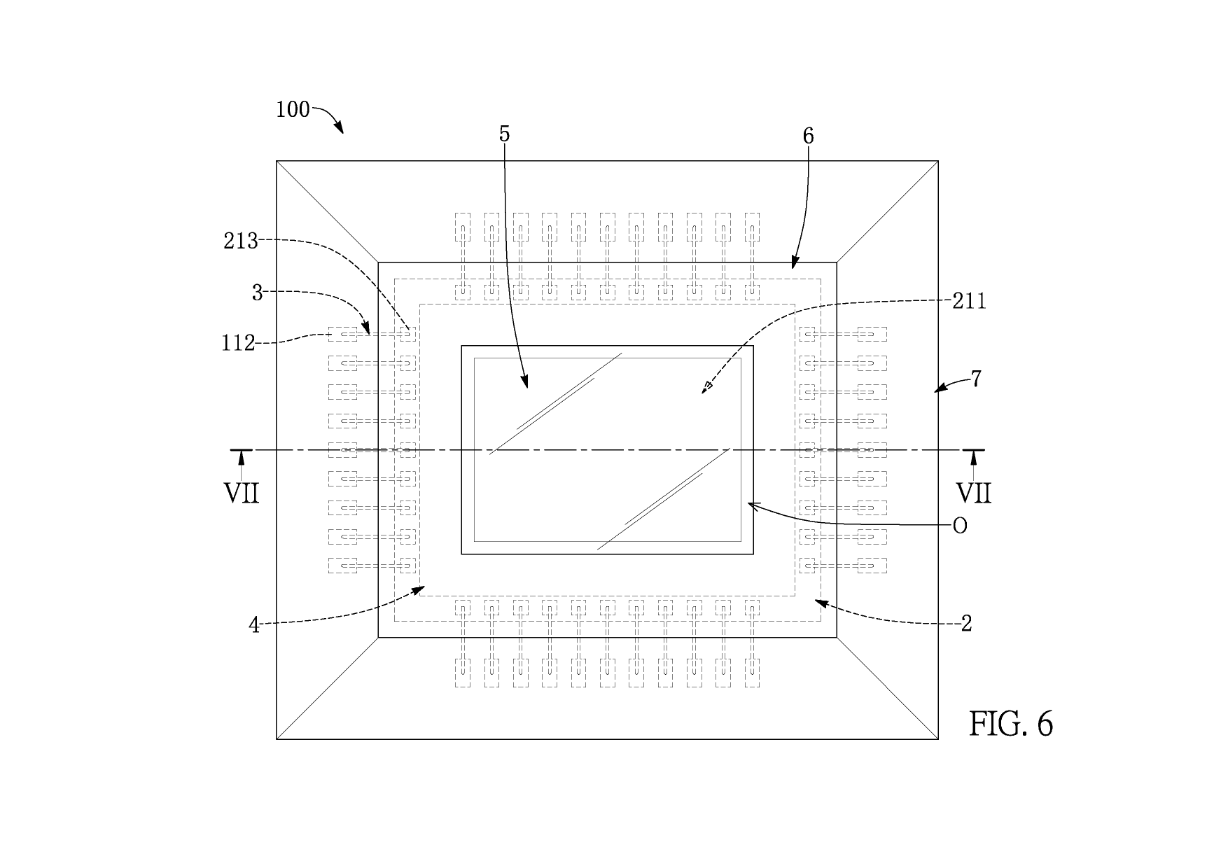

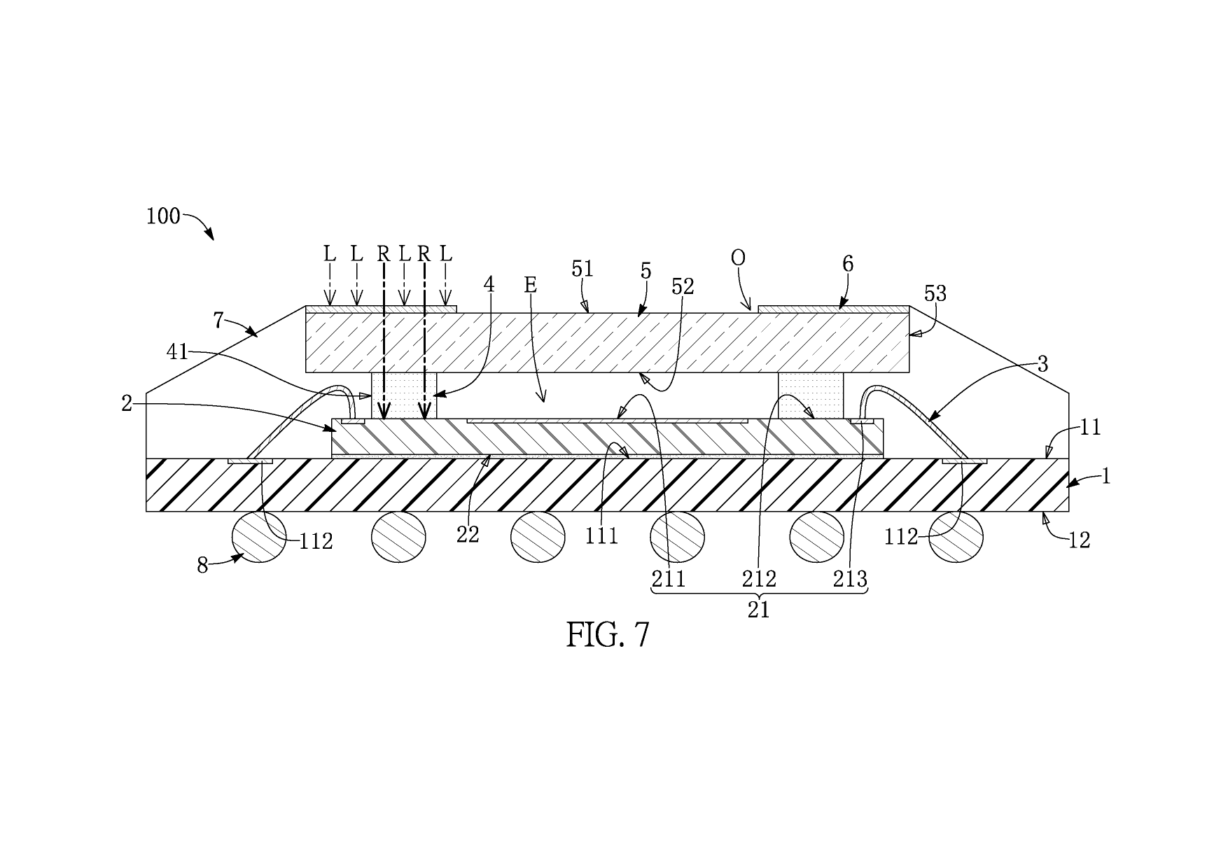

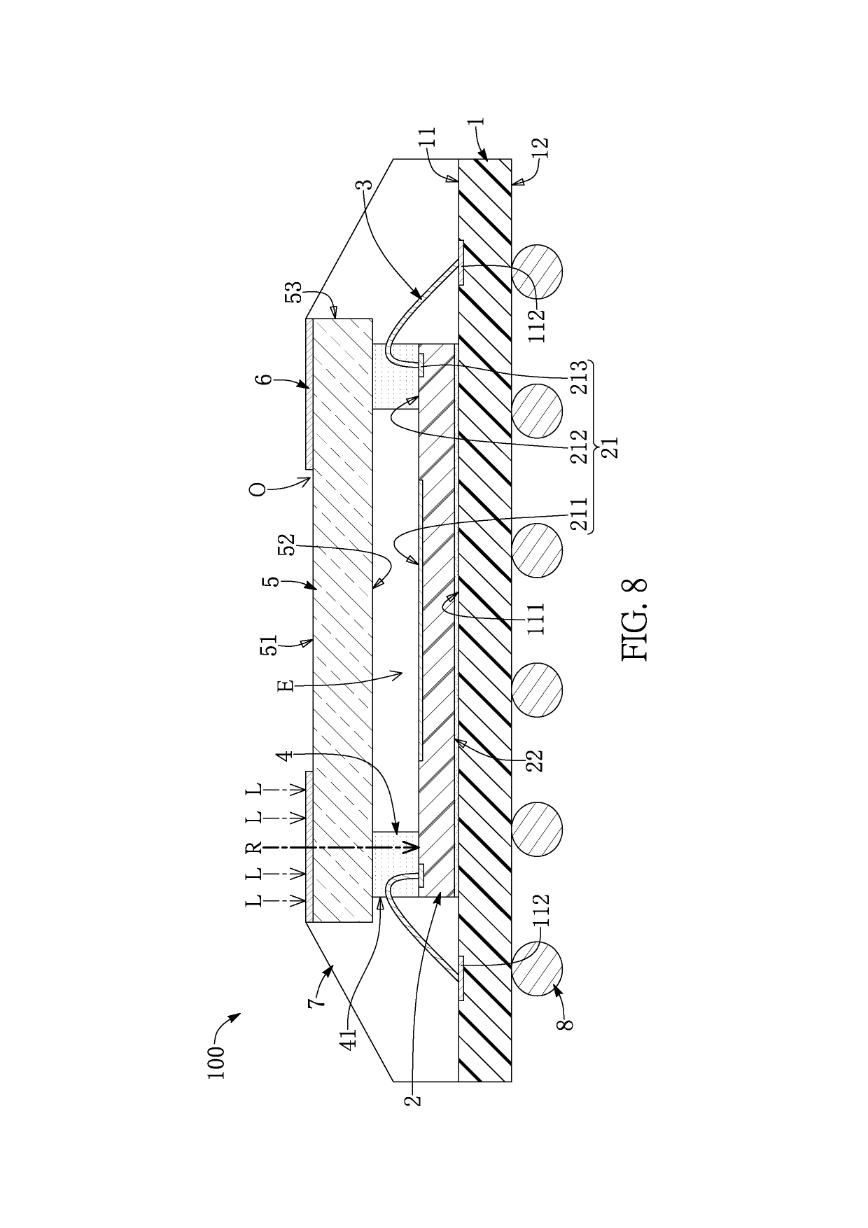

Referring to FIG. 5 to FIG. 8, a second embodiment of the present disclosure is provided, which is similar to the first embodiment of the present disclosure. For the sake of brevity, descriptions of the same components in the first and second embodiments of the present disclosure will be omitted herein, and the following description only discloses different features between the first and second embodiments.

In the present embodiment, the visible light shielding layer 6 is in a ringed shape and is disposed on the upper surface 51 of the light-permeable layer 5. The visible light shielding layer 6 has an opening O that is defined by an inner edge thereof and that is located directly above the sensing region 211, and an outer edge of the visible light shielding layer 6 is flush with the surrounding lateral surface 53 of the light-permeable layer 5 and is connected to the encapsulating body 7. Specifically, the infrared light curing layer 4 is located in a projection space defined by orthogonally projecting the visible light shielding layer 6 toward the substrate 1, and the visible light shielding layer 6 only allows the infrared light R to travel onto the infrared light curing layer 4 by passing therethrough.

### [Beneficial Effects of the Embodiments]

In conclusion, through structural cooperation between the infrared light curing layer and the visible light shielding layer, the sensor package structure of the present disclosure can provide a number of technical effects; for example, under a premise that the visible light shielding layer can block the visible light to reduce an effect of the glare phenomenon caused by the reflection from the infrared light curing layer, the visible light shielding layer only allows the infrared light to pass therethrough for solidifying the infrared light curing layer, so that the solidified shape of the infrared light curing layer can meet a predetermined condition, thereby enabling precise control of the levelness of the light-permeable layer.

Moreover, the sensor package structure provided by the present disclosure can be detected by the infrared light according to an optical property of the visible light shielding layer that only allows the infrared light to pass therethrough.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate including a plurality of soldering pads;
a sensor chip disposed on the substrate, wherein a top surface of the sensor chip includes a sensing region and a carrying region that surrounds the sensing region, wherein the plurality of soldering pads are arranged outside of the sensor chip, and the sensor chip includes a plurality of connection pads arranged on the carrying region;
an infrared light curing layer being in a ringed shape and disposed on the carrying region of the sensor chip;
a plurality of metal wires, wherein one end of each of the plurality of metal wires is connected to one of the plurality of soldering pads, and another end of each of the plurality of metal wires is connected to one of the plurality of connection pads;
a light-permeable layer arranged above the sensor chip through the infrared light curing layer, wherein the light-permeable layer has an upper surface and a lower surface that is opposite to the upper surface, and wherein the light-permeable layer, the infrared light curing layer, and the sensor chip jointly define an enclosed space, and the sensing region faces the light-permeable layer;
a visible light shielding layer being in a ringed shape and disposed on the lower surface of the light-permeable layer, wherein the visible light shielding layer is configured to block a visible light from passing therethrough, and the visible light shielding layer has an opening that is defined by an inner edge thereof and that is located directly above the sensing region, and wherein the visible light shielding layer has:
a normally shielding segment sandwiched between the light-permeable layer and the infrared light curing layer;
an inner laterally shielding segment that extends inwardly from the normally shielding segment and that is located in the enclosed space, wherein the opening is defined by an inner edge of the inner laterally shielding segment; and
an outer laterally shielding segment that extends outwardly from the normally shielding segment and that is arranged outside of the infrared light curing layer; and
an encapsulating body formed on the substrate, wherein the sensor chip, the infrared light curing layer, and the light-permeable layer are embedded in the encapsulating body, and a part of the light-permeable layer corresponding in position to the opening is exposed from the encapsulating body, and wherein each of the metal wires has two segments respectively embedded in the encapsulant and the infrared light curing layer, the outer laterally shielding segment is embedded in and connected to the encapsulating body, and the outer laterally shielding segment is free from contacting the metal wires;
wherein the infrared light curing layer, the plurality of connection pads, and a part of each of the metal wires are located in a projection space defined by orthogonally projecting the visible light shielding layer toward the substrate, and the visible light shielding layer only allows an infrared light to pass therethrough and travel onto the infrared light curing layer.

2. The sensor package structure according to claim 1, wherein an outer edge of the outer laterally shielding segment is flush with a surrounding lateral surface of the light-permeable layer.

3. The sensor package structure according to claim 1, wherein each of the plurality of connection pads and a part of the corresponding metal wire connected thereto are embedded in the infrared light curing layer.

4. The sensor package structure according to claim 1, wherein each of the plurality of metal wires has a bending part that is embedded in the infrared light curing layer and that is arranged adjacent to the normally shielding segment.

5. The sensor package structure according to claim 4, wherein the infrared light curing layer has an inner side and an outer side that is opposite to the inner side and that is connected to the encapsulating body, and the bending part of each of the plurality of metal wires is closer to the outer side than the inner side of the infrared light curing layer.

6. The sensor package structure according to claim 5, wherein the outer side of the infrared light curing layer is arranged inward by a distance from a surrounding lateral surface of the light-permeable layer.

7. The sensor package structure according to claim 1, wherein the inner laterally shielding segment is longer than the outer laterally shielding segment.

8. The sensor package structure according to claim 1, wherein the normally shielding segment is longer than the outer laterally shielding segment.

9. The sensor package structure according to claim 1, wherein the visible light shielding layer only allows the infrared light having a wavelength of at least 780 nm to pass therethrough and is configured to block the visible light having a wavelength within a range from 365 nm to 780 nm.

10. A sensor package structure, comprising:
a substrate including a plurality of soldering pads;
a sensor chip disposed on the substrate, wherein a top surface of the sensor chip includes a sensing region and a carrying region that surrounds the sensing region, wherein the plurality of soldering pads are arranged outside of the sensor chip, and the sensor chip includes a plurality of connection pads arranged on the carrying region;
an infrared light curing layer being in a ringed shape and disposed on the carrying region of the sensor chip;
a plurality of metal wires, wherein one end of each of the plurality of metal wires is connected to one of the plurality of soldering pads, and another end of each of the metal wires is connected to one of the plurality of connection pads;
a light-permeable layer arranged above the sensor chip through the infrared light curing layer, wherein the light-permeable layer has an upper surface and a lower surface that is opposite to the upper surface, and wherein the light-permeable layer, the infrared light curing layer, and the sensor chip jointly define an enclosed space, and the sensing region faces the light-permeable layer;
a visible light shielding layer being in a ringed shape and disposed on the lower surface of the light-permeable layer, wherein the visible light shielding layer is configured to block a visible light from passing therethrough, and the visible light shielding layer has an opening that is defined by an inner edge thereof and that is located directly above the sensing region; and
an encapsulating body formed on the substrate, wherein the sensor chip, the infrared light curing layer, and the light-permeable layer are embedded in the encapsulating body, and a part of the light-permeable layer corresponding in position to the opening is exposed from the encapsulating body, and wherein each of the plurality of metal wires is entirely embedded in the encapsulant, and the visible light shielding layer is free from contacting the plurality of metal wires;
wherein the infrared light curing layer, the plurality of connection pads, and a part of each of the plurality of metal wires are located in a projection space defined by orthogonally projecting the visible light shielding layer toward the substrate, and the visible light shielding layer only allows an infrared light to pass therethrough and travel onto the infrared light curing layer.

11. The sensor package structure according to claim 10, wherein an outer edge of the outer laterally shielding segment is flush with a surrounding lateral surface of the light-permeable layer.

12. The sensor package structure according to claim 10, wherein an outer portion of the sensor chip having the plurality of connection pads and arranged outside of the infrared light curing layer is embedded in and connected to the encapsulating body and is arranged in the projection space.

13. The sensor package structure according to claim 10, wherein the visible light shielding layer has:
a normally shielding segment sandwiched between the light-permeable layer and the infrared light curing layer;
an inner laterally shielding segment that extends inwardly from the normally shielding segment and that is located in the enclosed space, wherein the opening is defined by an inner edge of the inner laterally shielding segment; and
an outer laterally shielding segment that extends outwardly from the normally shielding segment and that is arranged outside of the infrared light curing layer, wherein the outer laterally shielding segment is longer than the inner laterally shielding segment.

14. The sensor package structure according to claim 13, wherein each of the plurality of metal wires has a bending part that is embedded in the encapsulating body and that is arranged adjacent to the outer laterally shielding segment.

15. The sensor package structure according to claim 14, wherein an outer portion of the sensor chip having the plurality of connection pads and arranged outside of the infrared light curing layer is embedded in and connected to the encapsulating body, and wherein the bending part of each of the plurality of metal wires is located in a space surroundingly defined by the outer portion of the sensor chip, the outer laterally shielding segment, and an outer side of the infrared light curing layer.

16. The sensor package structure according to claim 15, wherein the outer portion of the sensor chip is arranged in the projection space.

17. A sensor package structure, comprising:
a substrate;
a sensor chip disposed on the substrate, wherein a top surface of the sensor chip includes a sensing region and a carrying region that surrounds the sensing region;
an infrared light curing layer being in a ringed shape and disposed on the carrying region of the sensor chip;
a plurality of metal wires, wherein one end of each of the plurality of metal wires is connected to the substrate, and another end of each of the metal wires is connected to the sensor chip;
a light-permeable layer arranged above the sensor chip through the infrared light curing layer, wherein the light-permeable layer has an upper surface and a lower surface that is opposite to the upper surface, and wherein the light-permeable layer, the infrared light curing layer, and the sensor chip jointly define an enclosed space;
a visible light shielding layer being in a ringed shape and disposed on the lower surface of the light-permeable layer, wherein the visible light shielding layer has an opening that is defined by an inner edge thereof and that is located directly above the sensing region; and
an encapsulating body formed on the substrate, wherein the sensor chip, the infrared light curing layer, and the light-permeable layer are embedded in the encapsulating body, and a part of the light-permeable layer corresponding in position to the opening is exposed from the encapsulating body, and wherein each of the plurality of metal wires is at least partially embedded in the encapsulant and has a bending part that is arranged adjacent to the visible light shielding layer, and the visible light shielding layer is free from contacting the plurality of metal wires;
wherein the infrared light curing layer and the bending part of each of the plurality of metal wires are located in a projection space defined by orthogonally projecting the visible light shielding layer toward the substrate.

18. The sensor package structure according to claim 17, wherein an outer portion of the sensor chip connected to the plurality of metal wires and arranged outside of the infrared light curing layer is embedded in and connected to the encapsulating body and is arranged in the projection space.

19. The sensor package structure according to claim 17, wherein the bending part of each of the plurality of metal wires is embedded in the infrared light curing layer.

20. The sensor package structure according to claim 19, wherein the infrared light curing layer has an inner side and an outer side that is opposite to the inner side and that is connected to the encapsulating body, and the bending part of each of the plurality of metal wires is closer to the outer side than the inner side of the infrared light curing layer.
